(19) United States
(12) Patent Application Publication
(10) Pub. No.: US 2019/0347193 A1
(43) Pub. Date: Nov. 14, 2019

(54) MEMORY SYSTEM AND OPERATING METHOD THEREOF

(71) Applicant: SK hynix Inc., Gyeonggi-do (KR)

(72) Inventor: Eun-Soo JANG, Gyeonggi-do (KR)

(21) Appl. No.: 16/221,837

(22) Filed: Dec. 17, 2018

(30) Foreign Application Priority Data
May 8, 2018 (KR) 10-2018-0052256

(51) Int. Cl. G06F 12/02; G06F 3/06; G11C 16/16

(52) U.S. Cl. CPC G06F 12/0246; G06F 3/064; G11C 16/16; G06F 3/0679

(57) ABSTRACT

A memory system may include: a nonvolatile memory device including dies, each including planes, each including blocks, each including pages, each including a set number of sections, and page buffers for caching data to be outputted from the blocks by page unit; a host controller suitable for processing an operation with a host; and a memory controller coupled with the host controller, and suitable for processing an operation with the nonvolatile memory device, the memory controller: may check whether a read operation for a read-target block, among the blocks, is for a merge operation, may select whether to perform a page-buffer-caching-update operation of reading requested data from a page of the read-target block and caching the read data in a corresponding one of the page buffers based on a result of the check, and may receive the cached data from the corresponding page buffer.

### CROSS-REFERENCE TO RELATED APPLICATION

This application claims priority under 35 U.S.C. § 119(a) to Korean Patent Application No. 10-2018-0052256 filed on May 8, 2018, which is incorporated herein by reference in its entirety.

### BACKGROUND

### 1. Field

Various embodiments relate to a memory system, and more particularly, to a memory system including a nonvolatile memory device and an operating method thereof.

### 2. Discussion of the Related Art

The computer environment paradigm has shifted to ubiquitous computing systems that can be used anytime and anywhere. Due to this, use of portable electronic devices such as mobile phones, digital cameras, and notebook computers has rapidly increased. These portable electronic devices generally use a memory system having one or more memory devices for storing data. A memory system may be used as a main or an auxiliary storage device of a portable electronic device.

Memory systems provide excellent stability, durability, high information access speed, and low power consumption because they have no moving parts. Examples of memory systems having such advantages include universal serial bus (USB) memory devices, memory cards having various interfaces, and solid state drives (SSD).

### SUMMARY

Various embodiments are directed to a memory system capable of performing an efficient read operation and an operating method thereof.

In an embodiment, a memory system may include: a nonvolatile memory device including dies, each including planes, each including blocks, each including pages, each including a set number of sections, and page buffers for caching data to be outputted from the blocks by page unit; a host controller suitable for processing an operation with a host; and a memory controller coupled with the host controller, and suitable for processing an operation with the nonvolatile memory device, the memory controller: may check whether a read operation for a read-target block, among the blocks, is for a merge operation, may select whether to perform a page-buffer-caching-update operation of reading requested data from a page of the read-target block and caching the read data in a corresponding one of the page buffers based on a result of the check, and may receive the cached data from the corresponding page buffer.

In the case where the read operation is for a merge operation, the memory controller may check whether a target address of the read operation is the same as that of the most recently completed read operation, may select whether to perform the page-buffer-caching-update operation, depending on a result of the target address check, and may receive the cached data from the corresponding page buffer, and in the case where the read operation is not for a merge operation, the memory controller may perform the page-buffer-caching-update operation, and may receive the cached data from the corresponding page buffer.

In the case where the target address of the read operation is the same as that of a most recently completed read operation, the memory controller may do not perform the page-buffer-caching-update operation, and may receive the cached data from the corresponding page buffer, and in the case where the target address of the read operation is not the same as that of the most recently completed read operation, the memory controller may perform the page-buffer-caching-update operation, and may receive the cached data from the corresponding page buffer.

The memory system may further include a merge flag, the host controller may set the merge flag when requesting the read operation to the memory controller to perform the merge operation, and may reset the merge flag when requesting the read operation to the memory controller to perform an operation other than the merge operation, and the memory controller may determine whether the read operation is for the merge operation based on a state of the merge flag.

In the case of performing the merge operation, the host controller may provide information on victim blocks to the memory controller, and the memory controller may check whether the read-target block is included in the information on victim blocks, and may determine whether the read operation is for the merge operation based on a result of the check of the information on victim blocks.

The memory controller may manage a read-completed target address table which includes a set number of target addresses of most recently completed read operations and the memory controller may check whether the target address of the read operation is included in the read-completed target address table, and may determine whether the target address of the read operation is the same as that of the most recently completed read operation based on a result of the check of the read-completed target address table.

In the case where the target address of the read operation is included in the read-completed target address table, the memory controller may do not perform the page-buffer-caching-update operation, and may receive the cached data from the corresponding page buffer, and in the case where the target address of the read operation is not included in the read-completed target address table, the memory controller may perform the page-buffer-caching-update operation, and may receive the cached data from the corresponding page buffer.

The memory controller may transfer the cached data of a page unit received from the corresponding page buffer to the host controller by the page unit, or may divide the data by a section unit and transfers the divided data to the host controller by the section unit.

The memory controller may manage the blocks as a plurality of super blocks by grouping the blocks in a type corresponding to a set condition, and the memory controller may transfer the cached data of a super block unit received from the corresponding page buffer to the host controller by the super block unit, or may divide the requested data by a page unit and transfers divided data to the host controller by the page unit.

A first die of the dies is coupled to a first channel, a second die of the dies is coupled to a second channel, planes in the first die are coupled to first ways which share the first channel, and planes in the second die are coupled to a second ways which share the second channel, and according to the set condition the memory controller may group a first block in a first plane of the first die and a second block in a second plane of the first die and may group a third block in a third plane of the second die and a fourth block in a fourth plane of the second die, the memory controller may group a first block in a first plane of the first die and a third block in a third plane of the second die and may group a second block in a second plane of the first die and a fourth block in a fourth plane of the second die, or the memory controller may group a first block in a first plane of the first die, a second block in a second plane of the first die, a third block in a third plane of the second die and a fourth block in a fourth plane of the second die.

In an embodiment, a method for operating a memory system including a nonvolatile memory device including dies, each including planes, each including blocks, each including pages, each including a set number of sections, and page buffers for caching data to be outputted from the blocks, by page unit; a host controller suitable for processing an operation with a host; and a memory controller coupled with the host controller, and suitable for processing an operation with the nonvolatile memory device, the method may include: a first step of checking, by the memory controller, whether a read operation for a read-target block, among the blocks is for a merge operation; a first step of selecting whether to perform a page-buffer-caching-update operation of reading requested data from a page of the read-target block and caching read requested data in a corresponding one of the page buffers based on a result of the first checking step, through control of the memory controller; and transferring, after the first selecting step, the cached data from the corresponding page buffer of the nonvolatile memory device to the memory controller.

The first selecting step may include: a second step of checking, in the case where it is determined that the read operation is for a merge operation, whether a target address of the read operation is the same as that of the most recently completed read operation; a second step of selecting whether to perform the page-buffer-caching-update operation based on a result of the second checking step; and a first update step of performing the page-buffer-caching-update operation in the case where it is determined that the read operation is not for a merge operation, the transferring step may be performed after the second selecting step or the first update performing step.

The second selecting step may include: not performing the update operation in the case where it is determined that the target address of the read operation is the same as that of the most recently completed read operation; and a second update step of performing the page-buffer-caching-update operation in the case where it is determined that the target address of the read operation is not the same as that of the most recently completed read operation, the is transferring step may be performed after not performing the update operation or after the second update performing step.

The memory system may further include a merge flag, and the first checking step may include: setting the merge flag by the host controller when the host controller requests the read operation to the memory controller to perform the merge operation; resetting the merge flag by the host controller when the host controllers requests the read operation to the memory controller to perform an operation other than the merge operation; and determining, by the memory controller, whether the read operation is for the merge operation based on a state of the merge flag, when the read operation is requested to the memory controller.

The first checking step may include: providing, in the case of performing the merge operation, information on victim blocks to the memory controller by the host controller; and checking, when the read operation is requested to the memory controller, whether the read-target block is included in the information on victim blocks, and determining whether the read operation is for the merge operation based on a result of the checking the information on victim blocks, by the memory controller.

The second checking step may include: managing, by the memory controller, a read-completed target address table which includes a set number of target addresses of most recently completed read operations; and a third checking step of checking whether the is target address of the read operation is included in the read-completed target address table, and determining whether the target address of the read operation is the same as that of the most recently completed read operation based on a result of the third checking step.

The second selecting step may include: not performing the page-buffer-caching-update operation in the case where the target address of the read operation is included in the read-completed target address table; and a third update step of performing the page-buffer-caching-update operation in the case where the target address of the read operation is not included in the read-completed target address table, the transferring step may be performed after not performing the page-buffer-caching-update operation or after the third update performing step.

The transferring step may further include: transferring the requested data to the memory controller by page unit, and transferring the cached data to the host controller from the memory controller by page unit; or transferring the requested data to the memory controller by page unit, and dividing the received data by section unit, and transferring the divided data to the host controller from the memory controller by section unit.

The method may further include: managing, by the memory controller, the blocks as a plurality of super blocks by grouping the blocks in a type corresponding to a preset condition; transferring the cached data to the memory controller by super block unit in the is transferring step, and transferring the received cached data to the host controller from the memory controller by super block unit; and transferring the cached data to the memory controller by super block unit in the transferring step, and dividing the received cached data by page unit, and transferring the divided data to the host controller from the memory controller by page unit.

A first die of the dies is coupled to a first channel, a second die of the dies is coupled to a second channel, planes in the first die are coupled to first ways which share the first channel, and planes in the second die are coupled to second ways which share the second channel, wherein according to the set condition, the method may further include: grouping a first block in a first plane of the first die and a second block in a second plane of the first die and grouping a third block in a third plane of the second die and a fourth block in a fourth plane of the second die, grouping a first block in a first plane of the first die and a third block in a third plane of the second die and grouping a second block in a second plane of the first die and a fourth block in a fourth plane of the second die, or grouping a first block in a first plane of the first die, a second block in a second plane of the first die, a third block in a third plane of the second die and a fourth block in a fourth plane of the second die.

In an embodiment, a memory system may include: a memory device including pages, each of which is divided into two or more sections, and section buffers respectively coupled to the sections; and a controller configured to: control the memory device to perform a first read operation for a non-merge operation by caching data from a read-target page into the section buffers according to a read-target address; and control the memory device to perform a second read operation for a merge operation by outputting data currently cached in the sections by units of the sections without caching data from the read-target page into the section buffers when the read-target address of the second read operation is the same as a most recently completed read operation.

### BRIEF DESCRIPTION OF THE DRAWINGS

These and other features and advantages of the present invention will become apparent to those skilled in the art to which the present invention pertains from the following detailed description in reference to the accompanying drawings, wherein:

FIG. 1 is a block diagram illustrating a data processing system including a memory system in accordance with an embodiment of the present invention;

FIG. 2 is a schematic diagram illustrating an exemplary configuration of a memory device employed in the memory system shown in FIG. 1;

FIG. 3 is a circuit diagram illustrating an exemplary configuration of a memory cell array of a memory block in the memory device shown in FIG. 2;

FIG. 4 is a schematic diagram illustrating an exemplary three-dimensional structure of the memory device shown in FIG. 2;

FIGS. 5A to 5C are block diagrams to assist in the explanation of the configuration of a data processing system in accordance with an embodiment, by referring to FIG. 1;

FIG. 6 is a block diagram to assist in the explanation of the configuration of a memory system, with additional reference to FIGS. 5A to 5C, in accordance with an embodiment;

FIG. 7 is a diagram to assist in the explanation of an operation of managing a target address table in the memory system in accordance with the embodiment shown in FIG. 6;

FIGS. 8A to 8C are flow charts to assist in the explanation of a method for operating the memory system shown in FIGS. 5A to 7 in accordance with an embodiment; and

FIGS. 9 to 17 are diagrams schematically illustrating exemplary applications of the data processing system shown in FIG. 1 in accordance with various embodiments of the present invention.

### DETAILED DESCRIPTION

Various embodiments of the present invention are described below in more detail with reference to the accompanying drawings. However, elements and features of the present invention may be configured or arranged to form other embodiments, which may be modifications or variations of any of the disclosed embodiments. Thus, the present invention in not limited to the embodiments set forth herein. Rather, the described embodiments are provided so that this disclosure is thorough and complete and fully conveys the present invention to those skilled in the art to which this invention pertains. Throughout the disclosure, like reference numerals refer to like parts throughout the various figures and embodiments of the present invention. Also, throughout the specification, reference to “an embodiment” or the like is not necessarily to only one embodiment, and different references to any such phrase are not necessarily to the same embodiment(s).

It will be understood that, although the terms “first”, “second”, “third”, and so on may be used herein to identify various elements, these elements are not limited by these terms. These terms are used to distinguish one element from another element that otherwise have the same or similar names. Thus, a first element also in one instance may be termed a second or third element in another instance without departing from the spirit and scope of the present invention.

The drawings are not necessarily to scale and, in some instances, proportions may have been exaggerated in order to clearly illustrate features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present. Whether two elements are directly or indirectly connected/coupled, communication between the two elements may be wired or wireless, unless stated or the context indicates otherwise.

The terminology used herein is for the purpose of describing particular embodiments and is not intended to be limiting of the present invention. As used herein, singular forms are intended to include the plural forms and vice versa, unless the context clearly indicates otherwise. It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

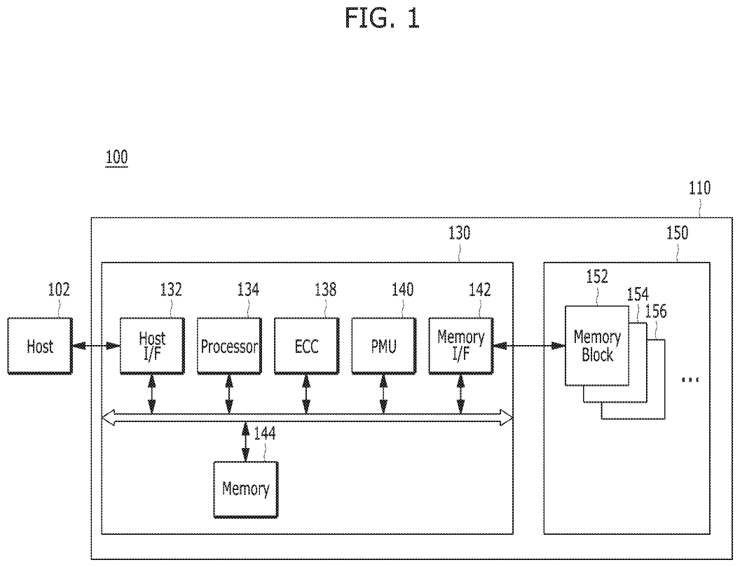

FIG. 1 is a block diagram illustrating a data processing system 100 including a memory system 110 in accordance with an embodiment of the present invention.

Referring to FIG. 1, the data processing system 100 may include a host 102 and the memory system 110.

The host 102 may include any of a variety of portable electronic devices such as a mobile phone, MP3 player and laptop computer or non-portable electronic devices such as a desktop computer, game machine, TV and projector.

The memory system 110 may operate to store data for the host 102 in response to a request of the host 102. Non-limiting examples of the memory system 110 include a solid state drive (SSD), a multi-media card (MMC), a secure digital (SD) card, a universal storage bus (USB) device, a universal flash storage (UFS) device, compact flash (CF) card, a smart media card (SMC), a personal computer memory card international association (PCMCIA) card and memory stick. The MMC may include an embedded MMC (eMMC), reduced size MMC (RS-MMC) and micro-MMC. The SD card may include a mini-SD card and micro-SD card.

The memory system 110 may be embodied by any of various types of storage devices. Non-limiting examples of storage devices included in the memory system 110 include volatile memory devices such as a DRAM dynamic random access memory (DRAM) and a static RAM (SRAM) and nonvolatile memory devices such as a read only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magneto-resistive RAM (MRAM), resistive RAM (RRAM) and a flash memory. The flash memory may have a 3-dimensional (3D) stack structure.

The memory system 110 may include a memory device 150 and a controller 130. The memory device 150 may store data for the host 120, and the controller 130 may control data storage into the memory device 150.

The controller 130 and the memory device 150 may be integrated into a single semiconductor device, which may be included in any of the various types of memory systems as exemplified above.

Non-limiting application examples of the memory system 110 include a computer, an Ultra Mobile PC (UMPC), a workstation, a net-book, a Personal Digital Assistant (PDA), a portable computer, a web tablet, a tablet computer, a wireless phone, a mobile phone, a smart phone, an e-book, a Portable Multimedia Player (PMP), a portable game machine, a navigation system, a black box, a digital camera, a Digital Multimedia Broadcasting (DMB) player, a 3-dimensional television, a smart television, a digital audio recorder, a digital audio player, a digital picture recorder, a digital picture player, a digital video recorder, a digital video player, a storage device constituting a data center, a device capable of transmitting/receiving information in a wireless environment, one of various electronic devices constituting a home network, one of various electronic devices constituting a computer network, one of various electronic devices constituting a telematics network, a Radio Frequency Identification (RFID) device, or one of various components constituting a computing system.

The memory device 150 may be a nonvolatile memory device retains data stored therein even though power is not supplied. The memory device 150 may store data provided from the host 102 through a write operation, and provide data stored therein to the host 102 through a read operation. The memory device 150 may include a plurality of memory dies (not shown), each memory die including a plurality of planes (not shown), each plane including a plurality of memory blocks 152 to 156, each of which may include a plurality of pages. Each of the pages may include a plurality of memory cells coupled to a word line.

The controller 130 may control the memory device 150 in response to a request from the host 102. For example, the controller 130 may provide data read from the memory device 150 to the host 102, and store data provided from the host 102 into the memory device 150. For this operation, the controller 130 may control read, write, program and erase operations of the memory device 150.

The controller 130 may include a host interface (I/F) 132, a processor 134, an error correction code (ECC) component 138, a Power Management Unit (PMU) 140, a memory interface (I/F) in the form of a NAND flash controller (NFC) 142 and a memory 144 all operatively coupled via an internal bus.

The host interface 132 may be configured to process a command and data of the host 102, and may communicate with the host 102 through one or more of various interface protocols such as universal serial bus (USB), multi-media card (MMC), peripheral component interconnect-express (PCI-E), small computer system interface (SCSI), serial-attached SCSI (SAS), serial advanced technology attachment (SATA), parallel advanced technology attachment (DATA), enhanced small disk interface (ESDI) and integrated drive electronics (IDE).

The ECC component 138 may detect and correct an error contained in the data read from the memory device 150. In other words, the ECC component 138 may perform an error correction decoding process to the data read from the memory device 150 through an ECC code used during an ECC encoding process. According to a result of the error correction decoding process, the ECC component 138 may output a signal, for example, an error correction success/fail signal. When the number of error bits is more than a threshold value of correctable error bits, the ECC component 138 may not correct the error bits, and may instead output an error correction fail signal.

The ECC component 138 may perform error correction through a coded modulation such as Low Density Parity Check (LDPC) code, Bose-Chaudhri-Hocquenghem (BCH) code, turbo code, Reed-Solomon code, convolution code, Recursive Systematic Code (RSC), Trellis-Coded Modulation (TCM) and Block coded modulation (BCM). However, the ECC component 138 is not limited to these correction techniques. As such, the ECC component 138 may include all circuits, modules, systems or devices for suitable error correction.

The PMU 140 may provide and manage power of the controller 130.

The NFC 142 may serve as a memory/storage interface for interfacing the controller 130 and the memory device 150 such that the controller 130 controls the memory device 150 in response to a request from the host 102. When the memory device 150 is a flash memory or specifically a NAND flash memory, the NFC 142 may generate a control signal for the memory device 150 and process data to be provided to the memory device 150 under the control of the processor 134. The NFC 142 may work as an interface (e.g., a NAND flash interface) for processing a command and data between the controller 130 and the memory device 150. Specifically, the NFC 142 may support data transfer between the controller 130 and the memory device 150.

The memory 144 may serve as a working memory of the memory system 110 and the controller 130, and store data for driving the memory system 110 and the controller 130. The controller 130 may control the memory device 150 to perform read, write, program and erase operations in response to a request from the host 102. The controller 130 may provide data read from the memory device 150 to the host 102, may store data provided from the host 102 into the memory device 150. The memory 144 may store data required for the controller 130 and the memory device 150 to perform these operations.

The memory 144 may be embodied by a volatile memory. For example, the memory 144 may be embodied by static random access memory (SRAM) or dynamic random access memory (DRAM). The memory 144 may be disposed within or externally to the controller 130. FIG. 1 shows the memory 144 disposed within the controller 130. In an embodiment, the memory 144 may be embodied by an external volatile memory having a memory interface transferring data between the memory 144 and the controller 130.

The processor 134 may control the overall operations of the memory system 110. The processor 134 may drive firmware to control the overall operations of the memory system 110. The firmware may be referred to as flash translation layer (FTL).

The processor 134 of the controller 130 may include a management unit (not illustrated) for performing a bad management operation of the memory device 150. The management unit may perform a bad block management operation of checking a bad block, in which a program fail occurs due to the characteristic of a NAND flash memory during a program operation, among the plurality of memory blocks 152 to 156 in the memory device 150. The management unit may write the program-failed data of the bad block to a new memory block. In the memory device 150 having a 3D stack structure, the bad block management operation may reduce the use efficiency of the memory device 150 and the reliability of the memory system 110. Thus, the bad block management operation needs to be performed with more reliability.

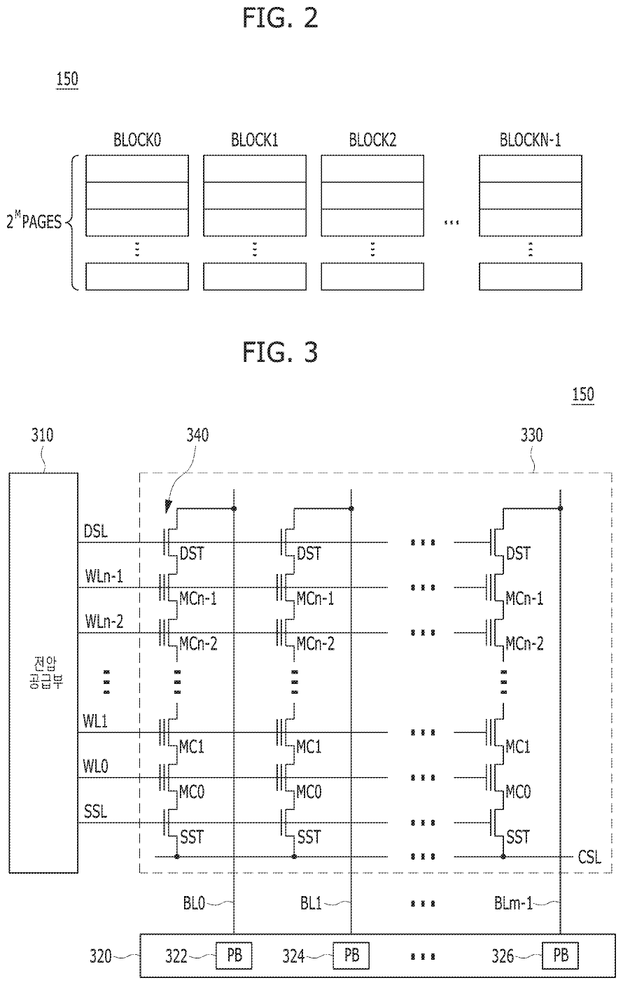

FIG. 2 is a schematic diagram illustrating the memory device 150.

Referring to FIG. 2, the memory device 150 may include a plurality of memory blocks 0 to N-1, and each of the blocks 0 to N-1 may include a plurality of pages, for example, 2^{M} pages, the number of which may vary according to circuit design. Memory cells included in the respective memory blocks 0 to N-1 may be one or more of a single level cell (SLC) storing 1-bit data, or a multi-level cell (MLC) storing 2- or more bit data. In an embodiment, the memory device 150 may include a plurality of triple level cells (TLC) each storing 3-bit data. In another embodiment, the memory device may include a plurality of quadruple level cells (QLC) each storing 4-bit level cell.

FIG. 3 is a circuit diagram illustrating an exemplary configuration of a memory cell array of a memory block in the memory device 150.

Referring to FIG. 3, a memory block 330, which may correspond to any of the plurality of memory blocks 152 to 156 in the memory device 150, may include a plurality of cell strings 340 coupled to a plurality of corresponding bit lines BL0 to BLm-1. The cell string 340 of each column may include one or more drain select transistors DST and one or more source select transistors SST. Between the drain and source select transistors DST and SST, a plurality of memory cells MC0 to MCn-1 may be coupled in series. In an embodiment, each of the memory cell transistors MC0 to MCn-1 may be embodied by an MLC capable of storing data information of a plurality of bits. Each of the cell strings 340 may be electrically coupled to a corresponding bit line among the plurality of bit lines BL0 to BLm-1. For example, as illustrated in FIG. 3, the first cell string is coupled to the first bit line BL0, and the last cell string is coupled to the last bit line BLm-1.

Although FIG. 3 illustrates NAND flash memory cells, the invention is not limited in this way. It is noted that the memory cells may be NOR flash memory cells, or hybrid flash memory cells including two or more kinds of memory cells combined therein. Also, it is noted that the memory device 150 may be a flash memory device including a conductive floating gate as a charge storage layer or a charge trap flash (CTF) memory device including an insulation layer as a charge storage layer.

The memory device 150 may further include a voltage supply 310 which provides word line voltages including a program voltage, a read voltage and a pass voltage to supply to the word lines according to an operation mode. The voltage generation operation of the voltage supply 310 may be controlled by a control circuit (not illustrated). Under the control of the control circuit, the voltage supply 310 may select one of the memory blocks (or sectors) of the memory cell array, select one of the word lines of the selected memory block, and provide the word line voltages to the selected word line and the unselected word lines as may be needed.

The memory device 150 may include a read/write circuit 320 which is controlled by the control circuit. During a verification/normal read operation, the read/write circuit 320 may operate as a sense amplifier for reading data from the memory cell array. During a program operation, the read/write circuit 320 may operate as a write driver for driving bit lines according to data to be stored in the memory cell array. During a program operation, the read/write circuit 320 may receive from a buffer (not illustrated) data to be stored into the memory cell array, and drive bit lines according to the received data. The read/write circuit 320 may include a plurality of page buffers 322 to 326 respectively corresponding to columns (or bit lines) or column pairs (or bit line pairs), and each of the page buffers 322 to 326 may include a plurality of latches (not illustrated).

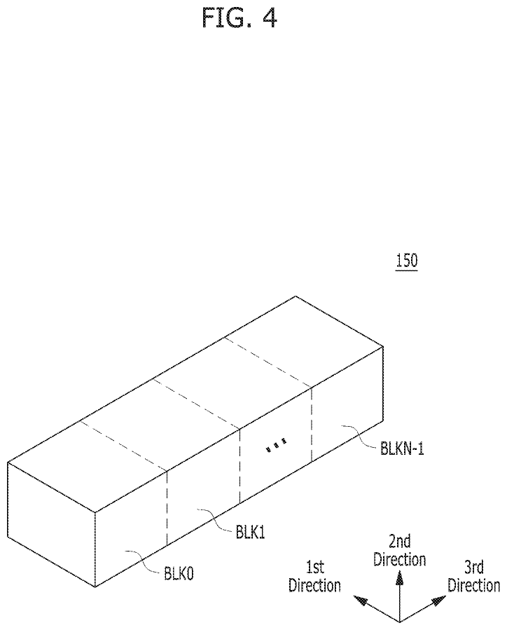

FIG. 4 is a schematic diagram illustrating an exemplary 3D structure of the memory device 150.

The memory device 150 may be embodied by a 2D or 3D memory device. Specifically, as illustrated in FIG. 4, the memory device 150 may be embodied by a nonvolatile memory device having a 3D stack structure. When the memory device 150 has a 3D structure, the memory device 150 may include a plurality of memory blocks BLK0 to BLKN-1 each having a 3D structure (or vertical structure).

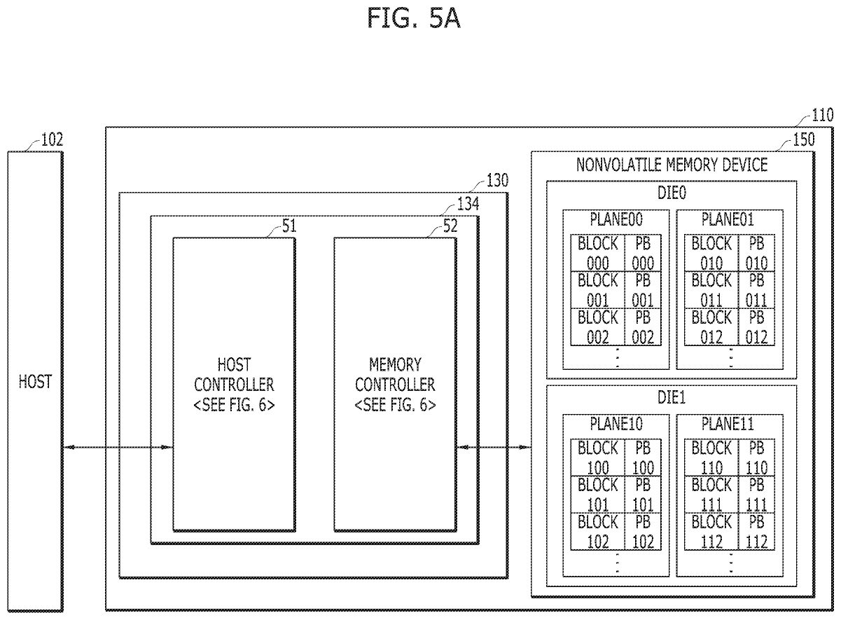

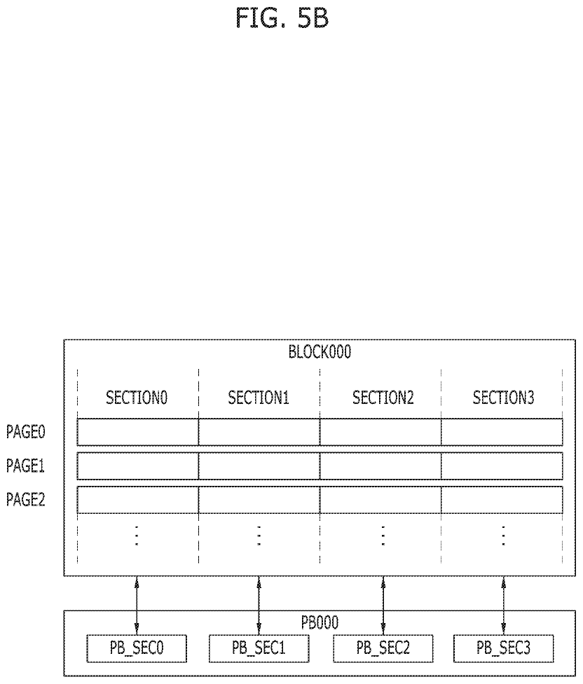

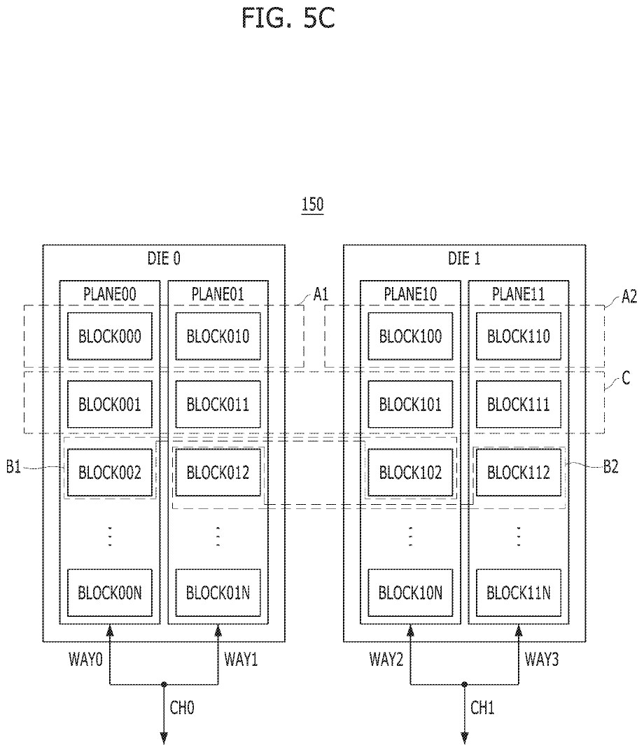

FIGS. 5A to 5C are block diagrams to assist in the explanation of the configuration of a data processing system, such as that illustrated in FIG. 1, in accordance with an embodiment.

FIGS. 5A and 5B illustrate a configuration of the data is processing system 100 including the host 102 and the memory system 110.

As described above with reference to FIG. 1, the memory system 110 includes the controller 130 and the nonvolatile memory device 150.

The controller 130 includes the processor 134. The processor 134 includes a host controller 51 and a memory controller 52.

As described above with reference to FIGS. 2 and 3, the nonvolatile memory device 150 includes a plurality of pages PAGEx, each including a plurality of memory cells, a plurality of blocks BLOCKxxx, each including multiple pages PAGEx, a plurality of planes PLANExx including the blocks BLOCKxxx, a plurality of dies DIE0 and DIE1 including the planes PLANExx, and page buffers PBxxx for caching data to be outputted from the blocks BLOCKxxx by the unit of page.

As shown in FIG. 5B, in the nonvolatile memory device 150 in accordance with the present embodiment, each of the pages PAGEx included in each of the blocks BLOCKxxx includes a set number of sections SECTION0 to SECTION3. That is to say, the sum of the numbers of memory cells in the set number of sections SECTION0 to SECTION3 will be the same as the number of memory cells in each of the pages PAGEx.

In correspondence to that each of the pages PAGEx includes the set number of sections SECTION0 to SECTION3, each of the page buffers PBxxx may have a set number of section page buffers PB_SEC0 to PB_SEC3.

Through the configuration that each of the PAGEx includes the sections SECTION0 to SECTION3, data smaller than page unit may be outputted.

For example, as shown in FIG. 5B, it may be assumed that four sections SECTION0 to SECTION3 are included in each page.

In order to output data by page unit, data should be outputted from all of four sections SECTION0 to SECTION3 through their corresponding four section page buffers PB_SEC0 to PB_SEC3.

For example, in order to output data having a smaller size than page unit, for example, data of three sections, data may be outputted by selecting less than all of the four sections, e.g., by selecting three sections among the four sections SECTION0 to SECTION3. In this regard, in the remaining non-selected section(s), dummy data or data not selected as an output target may be stored.

In order to select at least one section but less than all sections, among the four sections SECTION0 to SECTION3, and input/output data from the selected sections, the following method is used.

First, in the case of storing data in some sections selected among four sections SECTION0 to SECTION3, a scheme is used in which data to be inputted are cached in section page buffers corresponding to selected sections among four section page buffers PB_SEC0 to PB_SEC3, dummy data are cached in section page buffers corresponding to the remaining unselected sections, and the entire data (including the dummy data) cached in the four section page buffers PB_SEC0 to PB_SEC3 are programmed in the four sections SECTION0 to SECTION3.

In the case of outputting data from some sections selected among four sections SECTION0 to SECTION3, a scheme is used in which the entire data stored in the four sections SECTION0 to SECTION3 are read and cached in four section page buffers PB_SEC0 to PB_SEC3, only the data cached in section page buffers corresponding to selected sections among the four section page buffers PB_SEC0 to PB_SEC3 are selected and outputted, and the data cached in section page buffers corresponding to the remaining unselected sections are not outputted and erased.

In the case of supporting an operation of outputting data by a unit smaller than the page unit, that is, a section unit, in the nonvolatile memory device 150 as described above, whether the data stored in the nonvolatile memory device 150 is valid or invalid may be set by section unit.

For example, there may be a case in which, among the four sections SECTION0 to SECTION3 included in one specific page, the data stored in the zeroth and second sections SECTION0 and SECTION2 are valid data and the data stored in the first and third sections SECTION1 and SECTION3 are invalid data.

In this case, when performing a merge operation by selecting a memory block including the one specific page as a victim block, in order to move the valid data of the two sections SECTION0 and SECTION2 to a target block, the all data stored in the four sections SECTION0 to SECTION3 should be read twice.

In detail, after the all data stored in the four sections SECTION0 to SECTION3 included in the one specific page are read and cached in the four section page buffers PB_SEC0 to PB_SEC3, only the data cached in the zeroth section page buffer PB_SEC0 is selected and outputted, and the data cached in the remaining first to third section page buffers PB_SEC1, PB_SEC2 and PB_SEC3 are erased.

In succession, after the all data stored in the four sections SECTION0 to SECTION3 included in the one specific page are read and cached in the four section page buffers PB_SEC0 to PB_SEC3, only the data cached in the second section page buffer PB_SEC2 is selected and outputted, and the data cached in the remaining zeroth, first and third section page buffers PB_SEC0, PB_SEC1 and PB_SEC3 are erased.

In this way, due to supporting an operation of outputting data by the section unit, which is smaller than the page unit in the nonvolatile memory device 150, when performing a merge operation, there may be a case where a certain page is repeatedly read, which is an inefficient operation.

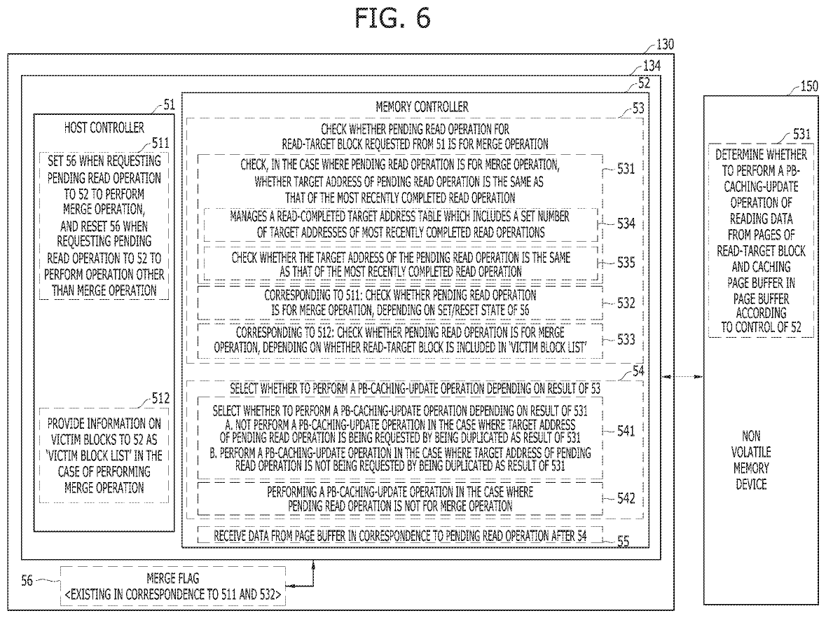

Therefore, in the memory system 110 in accordance with an embodiment of the present disclosure to be described below with reference to FIGS. 6 to 8C, the memory controller 52 may distinguish a read operation for a merge operation from a read operation for an operation other than a merge operation, and may prevent a read operation for the same page from being repeated, in the case of a read operation for a merge operation.

For reference, a merge operation may be a garbage collection operation, a read reclaim operation, a wear leveling operation or a map update operation.

FIG. 6 is a block diagram to assist in the explanation of the configuration of a memory system, e.g., memory system 110, in accordance with an embodiment, with additional reference to FIGS. 5A to 5C.

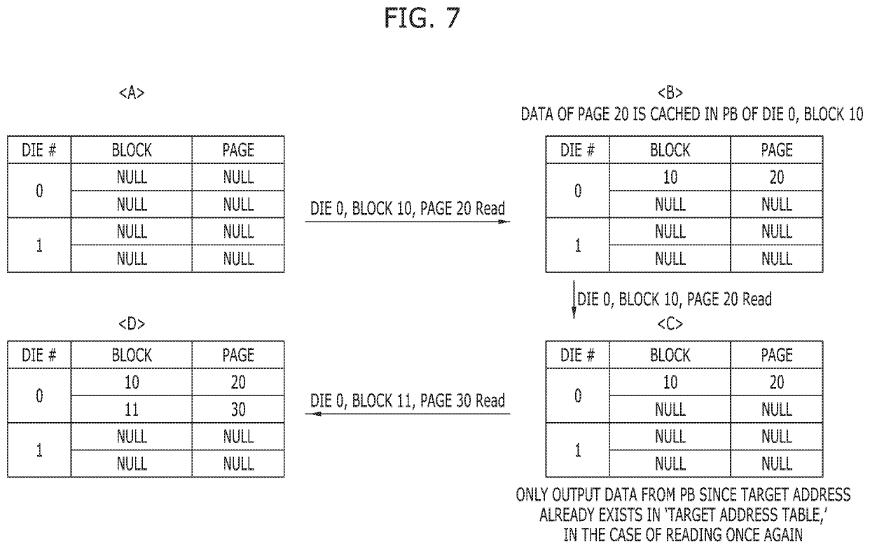

FIG. 7 is a diagram to assist in the explanation of an operation of managing a read-completed target address table in the memory system, e.g., memory system 110, in accordance with the embodiment shown in FIG. 6.

First, referring to FIG. 6, it may be seen that various details of a configuration of the memory system 110 described above with reference to FIGS. 5A and 5B are shown.

Concretely, the memory system 110 includes the controller 130 and the nonvolatile memory device 150.

As described above with reference to FIGS. 5A and 5B, the nonvolatile memory device 150 includes a plurality of pages PAGEx each including a set number of sections SECTION0 to SECTION3, each including a plurality of memory cells, a plurality of blocks BLOCKxxx, each including pages PAGEx, a plurality of planes PLANExx including the blocks BLOCKxxx, a plurality of dies DIE0 and DIE1 including the planes PLANExx, and page buffers PBxxx for caching data to be outputted from the blocks BLOCKxxx by the unit of page.

For reference, while a configuration in which only one nonvolatile memory device 150 is included in the memory system 110 is illustrated in FIGS. 5A, 5B and 6, this is by way of example only; a larger number of nonvolatile memory devices may be included.

The controller 130 includes the processor 134. The processor 134 includes the host controller 51 and the memory controller 52. The controller 130 may selectively further include a merge flag 56.

While FIGS. 5A, 5B and 6 do not illustrate a host interface 132, an ECC component 138, a power management unit 140, a NAND flash controller 142 and a volatile memory device 144, which are illustrated in FIG. 1, these components are omitted from FIGS. 5A, 5B and 6 for clarity; such components are included in the controller 130.

In detail, the host controller 51 processes an operation with the host 102.

The memory controller 52 is coupled with the host controller 51, and processes an operation with the nonvolatile memory device 150.

The memory controller 52 checks whether a read operation for a block requested from the host controller 51, e.g., a read-target block, is for a merge operation (step 53).

The memory controller 52 determines, depending on a checking result of step 53, whether to perform a PB-caching-update operation of reading data from a page of the read-target block and caching the read data in a page buffer in the nonvolatile memory device 150 (step 54).

After step 54 is performed, the memory controller 52 receives the data from the page buffer, in correspondence to the read operation (step 55).

In detail, at step 53, when a read operation is requested from the host controller 51 for the read-target block among the memory blocks BLOCKxxx, the memory controller 52 checks whether the read operation is for a merge operation.

For example, in the case where a read operation is requested from the host controller 51 for the zeroth block BLOCK000 among the memory blocks BLOCKxxx, the memory controller 52 checks whether the read operation for the zeroth block BLOCK000 is for a merge operation at step 53.

The memory controller 52 may select and use any one of the following two methods to perform step 53.

A first method entails performing step 53 by using the merge flag 56 included in the controller 130.

First, the host controller 51 sets the merge flag 56 when requesting a read operation to the memory controller 52 to perform a merge operation (511). Also, the host controller 51 resets the merge flag 56 when requesting a read operation to the memory controller 52 to perform an operation other than a merge operation, e.g., a non-merge operation (511).

The host controller 51 already knows whether a requested read operation is for a merge operation or for a non-merge operation. In other words, because the host controller 51 processes an operation with the host 102, the host controller 51 may be aware of whether a read operation directly requested from the host 102 is for a merge operation or for a non-merge operation. Also, because the host controller 51 processes an operation with the host 102, the host controller 51 may be aware of whether a read operation not directly requested from the host 102 but to be internally performed is for a merge operation or for a non-merge operation. Therefore, the host controller 51 may set or reset the merge flag 56 in step 511 at each time of requesting a read operation to the memory controller 52.

As step 511 is performed in the host controller 51 in this way, the memory controller 52 may check whether a read operation is for a merge operation or not, according to the set/reset state of the merge flag 56 (532).

For example, as a result of performing step 532 in response to a read operation requested from the host controller 51, in the case where the merge flag 56 is checked as a set state, the memory controller 52 may be aware that the requested read operation is for a merge operation.

Similarly, as a result of performing step 532 in response to a read operation requested from the host controller 51, in the case where the merge flag 56 is checked as a reset state, the memory controller 52 may be aware that the requested read operation is for a non-merge operation.

A second method entails performing step 53 by using a victim block list transferred from the host controller 51.

In detail, the host controller 51 provides, in the case of performing a merge operation, information on victim blocks, among the memory blocks BLOCKxxx, as the victim block list, to the memory controller 52 (512).

The host controller 51 may determine whether to perform a merge operation. Namely, after receiving, from the memory controller 52, various information on each of the memory blocks BLOCKxxx, for example, information on the number of valid pages, information on an access count and information on an erase-write count, the host controller 51 may determine whether to perform a merge operation, based on such information. Therefore, in the case of performing a merge operation by its own judgment, the host controller 51 may manage a victim block list for memory blocks to be used as victim blocks in the merge operation, and may provide the victim block list managed in this way to the memory controller 52 through step 512.

As step 512 is performed in the host controller 51 in this way, the memory controller 52 may check whether the read operation is for a merge operation or not, depending on a result of checking whether the read-target block is included in the victim block list (step 533).

For example, as a result of performing step 533 in response to a read operation requested from the host controller 51, in the case where it is determined that a read-target block is included in the victim block list, the memory controller 52 may be aware that the read operation is for a merge operation.

Similarly, as a result of performing step 533 in response to a read operation requested from the host controller 51, in the case where it is determined that a read-target block is not included in the victim block list, the memory controller 52 may be aware that the requested read operation is for a non-merge operation.

In the case where a read operation requested from the host controller 51 is for a merge operation, as determined in either step 532 or step 533, the memory controller 52 checks whether the target address of the requested read operation is the same as that of the most recently completed read operation (531).

For example, it may be assumed that the target address of a most recently completed read operation indicates the zeroth page PAGE0 of the zeroth block BLOCK000. The fact that the read operation for the zeroth page PAGE0 of the zeroth block BLOCK000 is completed means that the process of caching the requested data read from the zeroth page PAGE0 of the zeroth block BLOCK000 in the zeroth page buffer PG000 corresponding to the zeroth block BLOCK000, and step 55 of receiving the requested data by the memory controller 52 are completed.

In this state, in the case where the target address of a pending read operation is an address indicating the zeroth page PAGE0 of the zeroth block BLOCK000, it may be checked that the target address of the read operation is the same as that of the most recently completed read operation.

In the case where the target address of a pending read operation is an address indicating the first page PAGE1 of the zeroth block BLOCK000, it may be checked that the target address of the read operation is not the same as that of the most recently completed read operation.

In order to perform step 531, the memory controller 52 manages a read-completed target address table which includes a set number of target addresses of most recently completed read operations (step 534).

In step 534, the set number of the target addresses of read operations included in the read-completed target address table may be set variously depending on a designer's choice. For example, the number of all the memory blocks BLOCKxxx may be set as the number. Alternatively, by allocating N (N is a natural number of 1 or greater) to each of the dies DIE0 and DIE1, a total of 2*N may be set as the number.

Depending on whether the target address of a pending read operation is included in the read-completed target address table managed through step 534, the memory controller 52 may check whether the target address of the pending read operation is the same as that of the most recently completed read operation (535).

For example, referring to FIG. 7, it may be seen that the memory controller 52 manages the read-completed target address table which includes fields of die information, block information and page information. FIG. 7 shows two dies, DIE0 and DIE1, in the memory device 150.

At an initial stage <A> when no read operation is requested, no value is stored in the read-completed target address table.

After the initial stage <A>, the host controller 51 may request an operation “DIE0, BLOCK 10, PAGE 20 Read” of reading data from the 20th page (PAGE 20) of the 10th block (BLOCK 10) of the zeroth die (DIE0), to the memory controller 52, as a first read operation. The target address of the first read operation may be an address DIE0, BLOCK 10, PAGE 20 indicating the 20th page of the 10th block of the zeroth die.

As a result <B> of performing the first read operation, the data stored in the 20th page is cached in a page buffer corresponding to the 10th block of the zeroth die DIE0. That is to say, through the first read operation, the memory controller 52 reads the data stored in the 20th page of the 10th block of the zeroth die DIE0, caches the read data in a page buffer corresponding to the 10th block of the zeroth die DIE0, and receives the cached data. Also, as the result <B> of performing the first read operation, the memory controller 52 stores the target address of the first read operation, that is, the address DIE0, BLOCK 10, PAGE 20 indicating the 20th page of the 10th block of the zeroth die, in the read-completed target address table for the zeroth die DIE0.

After the first read operation is performed the host controller 51 may request an operation “DIE0, BLOCK 10, PAGE 20 Read” of reading data from the 20th page of the 10th block of the zeroth die, to the memory controller 52, as a second read operation. The target address of the second read operation will be the address DIE0, BLOCK 10, PAGE 20 indicating the 20th page of the 10th block of the zeroth die.

The memory controller 52 checks whether the target address of the second read operation exists in the read-completed target address table. Through this, the memory controller 52 may check that it is a state that the target address of the second read operation already exists in the read-completed target address table.

Therefore, the memory controller 52 does not newly store the target address of the second read operation in the read-completed is target address table, and manages the read-completed target address table in such a way as to retain the already stored target address of the first read operation as it is. In other words, as a result <C> of performing the second read operation, the memory controller 52 retains the target address of the first read operation, that is, the address DIE0, BLOCK 10, PAGE 20 indicating the 20th page of the 10th block of the zeroth die, as it is, in the read-completed target address table for the zeroth die DIE0.

As the result <C> of performing the second read operation, the data stored in the 20̂th page is still cached in the page buffer corresponding to the 10̂th block of the zeroth die DIE0. Namely, because it is checked through the read-completed target address table that the target address of the second read operation and the target address of the first read operation are the same, the memory controller 52 does not read data from the 20th page of the 10th block of the zeroth die in the process of performing the second read operation, and only receives the data already cached in the page buffer corresponding to the 10th block of the zeroth die DIE0 in the process of performing the first read operation.

After the second read operation is performed <C>, the host controller 51 may request an operation “DIE0, BLOCK 11, PAGE 30 Read” of reading data from the 30th page of the 11th block of the zeroth die, to the memory controller 52, as a third read operation. The target address of the third read operation may be an address DIE0, BLOCK 11, PAGE 30 indicating the 30th page of the 11th block of the zeroth die.

The memory controller 52 checks whether the target address of the third read operation exists in the read-completed target address table. Through this, the memory controller 52 may be aware that the target address of the third read operation does not exist in the read-completed target address table.

Thus, the memory controller 52 newly stores the target address of the third read operation in the read-completed target address table. That is to say, as a result <D> of performing the third read operation, the memory controller 52 is in a state in which it stores the target address of the first read operation and the second read operation, that is, the address DIE0, BLOCK 10, PAGE 20 indicating the 20th page of the 10th block of the zeroth die, together with the target address of the third read operation, that is, the address DIE0, BLOCK 11, PAGE 30 indicating the 30th page of the 11th block of the zeroth die, in the read-completed target address table for the zeroth die DIE0.

Referring back to FIG. 6, at step 54, the memory controller 52 selects, depending on a checking result of step 53, whether to perform a PB-caching-update operation in the nonvolatile memory device 150.

The PB-caching-update operation means an operation of reading data from a page of a read-target block and caching the read data in a page buffer corresponding to the read-target block.

For example, referring to FIG. 5B together with FIG. 6, consider the case that the zeroth block BLOCK000 is a read-target block and data stored in any one page read-requested among the pages PAGEx in the zeroth block BLOCK000 is requested data. Therefore, an operation of reading and caching requested data from a page read-requested among the pages PAGEx of the zeroth block BLOCK000 in the zeroth page buffer PG000 may be considered as the PB-caching-update operation.

In this way, at step 54, the memory controller 52 selects whether to perform a PB-caching-update operation. In other words, the nonvolatile memory device 150 selects whether to perform a PB-caching-update operation, according to the control of the memory controller 52 (541).

Step 531 is an operation of checking whether the target address of a pending read operation is the same as that of the most recently completed read operation, in the case where it is checked through step 532 or step 533 that the pending read operation is for a merge operation.

Hence, step 531 may be divided into a case where the target address of the pending read operation is the same as that of the most recently completed read operation and a case where the target address of the pending read operation is not the same as that of the most recently completed read operation, in a state in which it is determined that the pending read operation is for a merge operation.

In the case in which the target address of the pending read operation is the same as that of the most recently completed read operation, the memory controller 52 controls, through step 54, the nonvolatile memory device 150 not to perform a PB-caching-update operation (541A).

Conversely, in the case in which the target address of the pending read operation is not the same as that of the most recently completed read operation, the memory controller 52 controls, through step 54, the nonvolatile memory device 150 to perform a PB-caching-update operation (541B).

Step 532 or step 533 is an operation of checking whether the read operation is for a merge operation.

In the case in which the read operation is determined to be for a merge operation, step 531 is performed.

Conversely, in the case in which the read operation is determined to be for a non-merge operation, the memory controller 52 controls, through step 54, the nonvolatile memory device 150 to perform a PB-caching-update operation (542).

After step 54 is performed, the memory controller 52 receives the data from the page buffer in correspondence to the read operation (55).

For example, in the case where it is assumed as described above that the zeroth page buffer PG000 is a target of the PB-caching-update operation, data read from the block BLOCK000 may be cached in the zeroth page buffer PG000, regardless of whether it is determined at step 54 to perform a PB-caching-update operation to the page buffer PG000. Thus, at step 55, the memory controller 52 receives the data cached in the zeroth page buffer PG000, in response to the read operation from the host controller 51, and then, transfers the received data to the host controller 51.

Summarizing this, in the case of supporting an operation of outputting data by a unit smaller than page (section unit) in the nonvolatile memory device 150 as described above with reference to FIGS. 5A and 5B, in correspondence to a read operation, the memory controller 52 may transfer requested data of page unit received from a page buffer, to the host controller 51 by page unit, but may divide requested data by section unit and transfer the requested data to the host controller 51 by section unit.

In this regard, in the case where valid/invalid section data are stored by being distributed in a plurality of sections included in a specific page, there may occur a case where repeated read operations (PB-caching-update operations) for the specific page are caused to be performed in a read operation for a merge operation.

As is apparent from the above description, the memory controller 52 of the memory system 110 in accordance with embodiments determines whether a read operation for a specific page requested from the host controller 51 is for a merge operation or for a is non-merge operation, receives, in the case where the read operation is for a merge operation, data cached in a specific page buffer by performing a PB-caching-update operation for a specific page only in the case where the read operation is a first read operation, and receives, in a subsequent read operation, the data cached in the specific page buffer in a state in which a PB-caching-update operation for the specific page is not performed. Through this, by minimizing PB-caching-update operations to be performed in the nonvolatile memory device 150 when a read operation for a merge operation is requested, it is possible to prevent an unnecessary PB-caching-update operation to be performed in the read operation for a merge operation.

In the memory system 110 in accordance with an embodiment, a method for minimizing a PB-caching-update operation to be performed in the case where a read operation for a merge operation is performed for each of the memory blocks BLOCKxxx was described.

However, referring to FIG. 5C, it may be seen that it is also possible to group the memory blocks BLOCKxxx into a plurality of super blocks in a form corresponding to a set condition and then output data by the unit of super block.

In detail, referring to FIG. 5C to explain the concept of a super block, the nonvolatile memory device 150 includes a zeroth memory die DIE0 capable of outputting data through a zeroth channel CH0 and a first memory die DIE1 capable of outputting data through a first channel CHI. The zeroth channel CH0 and the first channel CH1 may output data in an interleaving scheme.

The zeroth memory die DIE0 includes a plurality of planes, e.g., PLANE00 and PLANE01, respectively corresponding to a plurality of ways, e.g., WAY0 and WAY1, capable of outputting data in the interleaving scheme by sharing the zeroth channel CH0.

The first memory die DIE1 includes a plurality of planes, e.g., PLANE10 and PLANE11, respectively corresponding to a plurality of ways, e.g., WAY2 and WAY3, capable of outputting data in the interleaving scheme by sharing the first channel CH1.

In this manner, the plurality of memory blocks BLOCKxxx may be divided according to physical positions such as using the same ways or the same channels.

Further, different from the scheme of dividing the plurality of memory blocks BLOCKxxx according to physical positions such as the plurality of memory dies DIE0 and DIE1 or the plurality of planes PLANExx, the controller 130 may use a scheme of dividing a plurality of memory blocks according to simultaneous selection and operation of memory blocks. That is to say, the controller 130 may manage a plurality of memory blocks which are divided into different dies or different planes through the dividing scheme according to physical positions, by grouping memory blocks capable of being selected simultaneously among the plurality of memory blocks and thereby dividing the plurality of memory blocks into super memory blocks.

The scheme of grouping, in this manner, the plurality of memory blocks BLOCKxxx into super memory blocks by the controller 130 may be carried out by various schemes according to a designer's choice. Three schemes are specifically described herein.

A first scheme is to manage one super memory block A1 by grouping, using the controller 130, one memory block BLOCK000 in the first plane PLANE00 and one memory block BLOCK010 in the second plane PLANE01 of the zeroth memory die DIE0. When applying the first scheme to the first memory die DIE1, the controller 130 may manage one super memory block A2 by grouping one memory block BLOCK100 in the first plane PLANE10 and one memory block BLOCK110 in the second plane PLANE11 of the first memory die DEL

A second scheme is to manage one super memory block Bi by grouping, by the controller 130, one memory block BLOCK002 in the first plane PLANE00 of the zeroth memory die DIE0 and one memory block BLOCK102 in the first plane PLANE10 of the first memory die DIE1. When applying the second scheme again, the controller 130 may manage one super memory block B2 by grouping one memory block BLOCK012 in the second plane PLANE01 of the zeroth memory die DIE0 and one memory block BLOCK112 in the second plane PLANE11 of the first memory die DIE1.

A third scheme is to manage one super memory block C by is grouping, using the controller 130, one memory block BLOCK001 in the first plane PLANE00 of the zeroth memory die DIE0, one memory block BLOCK011 in the second plane PLANE01 of the zeroth memory die DIE0, one memory block BLOCK101 in the first plane PLANE10 of the first memory die DIE1 and one memory block BLOCK111 in the second plane PLANE11 of the first memory die DIE1.

For reference, memory blocks capable of being selected simultaneously as a result of being included in the same super memory block may be selected substantially simultaneously through an interleaving scheme, for example, a channel interleaving scheme, a memory die interleaving scheme, a memory chip interleaving scheme or a way interleaving scheme.

In the case where, as shown in FIG. 5C, the memory controller 52 manages the plurality of memory blocks BLOCKxxx by grouping them into a plurality of super blocks according to a set condition, the size of data to be exchanged between the nonvolatile memory device 150 and the memory controller 52 may correspond to a super block unit.

Therefore, while the memory controller 52 may transfer requested data received from a page buffer of the nonvolatile memory device 150 in correspondence to a read operation from the host controller 51, to the host controller 51 by super block unit, the memory controller 52 may also divide the requested data into page unit and transfer the requested data to the host controller 51 by page unit.

In this regard, in the case where valid/invalid page data are stored by being distributed in a plurality of pages included in a specific super block, there may occur a case where repeated read operations (PB-caching-update operations) for the entirety of the plurality of pages in the specific super block are caused to be performed in a read operation for a merge operation.

Thus, the memory controller 52 of the memory system 110 in accordance with an embodiment determines whether a read operation for a plurality of pages in a specific super block requested from the host controller 51 is for a merge operation or for a non-merge operation, receives, in the case where the read operation is for a merge operation, data cached in a page buffer for the specific super block by performing a PB-caching-update operation for the plurality of pages in the specific super block only in the case where the read operation is a first read operation, and receives, in a subsequent read operation, the data cached in the page buffer for the specific super block in a state in which a PB-caching-update operation for the plurality of pages included in the specific super block is not performed. Through this, by minimizing a PB-caching-update operation to be performed in the nonvolatile memory device 150 when a read operation for a merge operation is requested, it is possible to prevent an unnecessary PB-caching-update operation to be performed in the read operation for a merge operation.

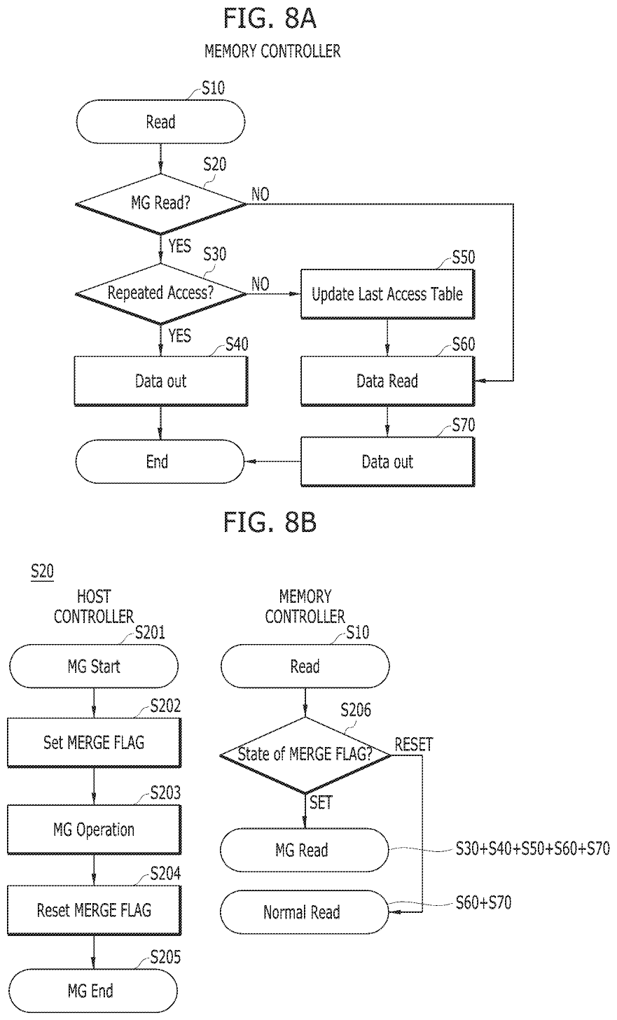

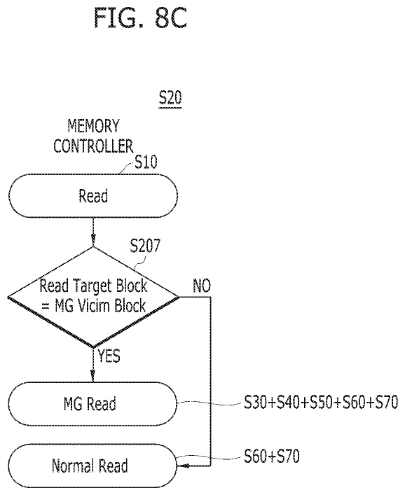

FIGS. 8A to 8C are flow charts to assist in the explanation of operations of the memory system 110 in accordance with embodiments shown in FIGS. 5A to 7.

First, referring to FIG. 8A, it may be seen in which sequence the memory controller 52 processes a read operation requested from the host controller 51.

In detail, in response to that a read operation is requested from the host controller 51, the operation of the memory controller 52 is started (step S10).

The memory controller 52 checks whether the read operation requested from the host controller 51. in step S10 is for a merge operation (MG) (step S20).

In the case where the requested read operation requested is for an operation other than a merge operation (MG) (NO at step S20), requested data are read from the pages of a read-target block by performing a PB-caching-update operation and are cached in a page buffer (step S60). Then, the requested data cached in the page buffer are outputted to the memory controller 52 (step S70).

In the case where it is determined at step S20 that the read operation requested from the host controller 51 is for a merge operation (MG) (YES at step S20), it is checked whether the target address of the requested read operation is the same as that of the most recently completed read operation (step S30).

In the case where it is determined at step S30 that the target address of the requested read operation is the same as that of the most recently completed read operation (YES at step S30), requested data cached in a page buffer corresponding to the target address are outputted to the memory controller 52 without performing a PB-caching-update operation (step S40).

In the case where it is determined at step S30 that the target address of the requested read operation is not the same as that of the most recently completed read operation (NO at step S30), the target address of the requested read operation is newly updated in a read-completed target address table (step S50), and then, requested data are read from the pages of a read-target block by performing a PB-caching-update operation and are cached in a page buffer corresponding to the target address (step S60). Then, the requested data cached in the page buffer are outputted to the memory controller 52 (step S70).

Referring to FIGS. 8B and 8C, further operations of step S20 are described.

In detail, referring to FIG. 8B, when starting a merge operation (step S201), the host controller 51 sets the merge flag 56 which is included in the controller 130 (step S202).

After step S202, the host controller 51 performs a merge operation (step S203), and resets, when ending the performing of the merge operation (S205), the merge flag 56 which is included in the controller 130 (S204).

Referring to FIG. 8C, when the read operation requested from the host controller 51 is started (step S10), the memory controller 52 checks the state of the merge flag 56 which is included in the controller 130 (step S206),

As a result of the checking at step 5206, when the merge flag 56 is in a set state, it may be seen that the requested read operation is for a merge operation, and thus the read operation for a merge operation (i.e., steps S30+S40+S50+S60+S70), described above with reference to FIG. 8A, is performed.

As a result of the checking at step 5206, when the merge flag 56 is in a reset state, it may be seen that the requested read operation is for a non-merge operation, the read operation for a non-merge operation (i.e., steps 560+570), described above with reference to FIG. 8A, is performed.

In detail, referring to FIG. 8C, when the read operation requested from the host controller 51 is started (step S10), the memory controller 52 checks whether a read-target block is included in a victim block list for merge operation (step S207).

As a result of the checking at step S207, in the case where it s checked that a read-target block is included in a victim block list for merge operation (YES at step S207), it may be seen that the requested read operation is for a merge operation, and thus the read operation for a merge operation (i.e., steps 530+S40+S50+560+S70), described above with reference to FIG. 8A, is performed.

As a result of the checking at step S207, in the case where it is determined that a read-target block is not included in a victim block list for merge operation (NO at step S207), it may be seen that the requested read operation is for a non-merge operation, and thus the read operation for a non-merge operation (i.e., steps S60+570), described above with reference to FIG. 8A, is performed.

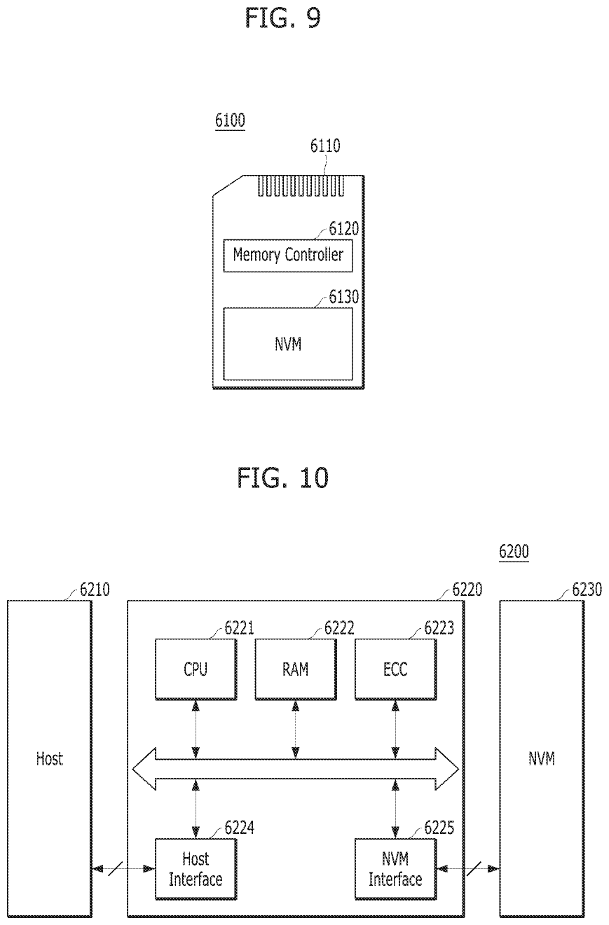

Detailed description will be made with reference to FIGS. 9 to 17, for a data processing system and electronic appliances to which the memory system 110 including the memory device 150 and the controller 130, described above with reference to FIGS. 1 to 8C, may be applied, in accordance with embodiments of the present disclosure.

FIGS. 9 to 17 are diagrams schematically illustrating exemplary applications of the data processing system of FIG. 1.

FIG. 9 is a diagram schematically illustrating another example of the data processing system including the memory system in accordance with an embodiment. FIG. 9 schematically illustrates a memory card system to which the memory system may be applied.

Referring to FIG. 9, the memory card system 6100 may include a memory controller 6120, a memory device 6130 and a connector 6110.

More specifically, the memory controller 6120 may be connected to the memory device 6130 embodied by a nonvolatile memory, and configured to access the memory device 6130. For example, the memory controller 6120 may be configured to control read, write, erase and background operations of the memory device 6130. The memory controller 6120 may be configured to provide an interface between the memory device 6130 and a host, and drive firmware for controlling the memory device 6130. That is, the memory controller 6120 may correspond to the controller 130 of the memory system 110 described with reference to FIGS. 1 and 5, and the memory device 6130 may correspond to the memory device 150 of the memory system 110 described with reference to FIGS. 1 and 5.

Thus, the memory controller 6120 may include a RAM, a processing unit, a host interface, a memory interface and an error correction unit. The memory controller 130 may further include the elements shown in FIG. 5.

The memory controller 6120 may communicate with an external device, for example, the host 102 of FIG. 1 through the connector 6110. For example, as described with reference to FIG. 1, the memory controller 6120 may be configured to communicate with an external device through one or more of various communication protocols such as universal serial bus (USB), multimedia card (MMC), embedded MMC (eMMC), peripheral component interconnection (PCI),

PCI express (PCIe), Advanced Technology Attachment (ATA), Serial-ATA, Parallel-ATA, small computer system interface (SCSI), enhanced small disk interface (EDSI), Integrated Drive Electronics (IDE), Firewire, universal flash storage (UFS), WIFI and Bluetooth. Thus, the memory system and the data processing system may be applied to wired/wireless electronic devices, particularly mobile electronic devices.

The memory device 6130 may be implemented by a nonvolatile memory. For example, the memory device 6130 may be implemented by various nonvolatile memory devices such as an erasable and programmable ROM (EPROM), an electrically erasable and programmable ROM (EEPROM), a NAND flash memory, a NOR flash memory, a phase-change RAM (PRAM), a resistive RAM (ReRAM), a ferroelectric RAM (FRAM) and a spin torque transfer magnetic RAM (STT-RAM). The memory device 6130 may include a plurality of dies as in the memory device 150 of FIG. 5.

The memory controller 6120 and the memory device 6130 may be integrated into a single semiconductor device. For example, the memory controller 6120 and the memory device 6130 may be so integrated to form a solid state driver (SSD). Also, the memory controller 6120 and the memory device 6130 may form a memory card such as a PC card (PCMCIA: Personal Computer Memory Card International Association), a compact flash (CF) card, a smart media card (e.g., SM and SMC), a memory stick, a multimedia card (e.g., MMC, RS-MMC, MMCmicro and eMMC), an SD card (e.g., SD, miniSD, microSD and SDHC) and a universal flash storage (UFS).

FIG. 10 is a diagram schematically illustrating another example of the data processing system including the memory system in accordance with an embodiment.

Referring to FIG. 10, the data processing system 6200 may include a memory device 6230 having one or more nonvolatile memories and a memory controller 6220 for controlling the memory device 6230. The data processing system 6200 illustrated in FIG. 10 may serve as a storage medium such as a memory card (CF, SD, micro-SD or the like) or USB device, as described with reference to FIG. 1. The memory device 6230 may correspond to the memory device 150 in the memory system 110 illustrated in FIGS. 1 and 5, and the memory controller 6220 may correspond to the controller 130 in the memory system 110 illustrated in FIGS. 1 and 5.

The memory controller 6220 may control a read, write or erase operation on the memory device 6230 in response to a request of the host 6210, and the memory controller 6220 may include one or more CPUs 6221, a buffer memory such as RAM 6222, an ECC circuit 6223, a host interface 6224 and a memory interface such as an NVM interface 6225.

The CPU 6221 may control overall operations on the memory device 6230, for example, read, write, file system management and bad page management operations. The RAM 6222 may be operated according to control of the CPU 6221, and used as a work memory, buffer memory or cache memory. When the RAM 6222 is used as a work memory, data processed by the CPU 6221 may be temporarily stored in the RAM 6222. When the RAM 6222 is used as a buffer is memory, the RAM 6222 may be used for buffering data transmitted to the memory device 6230 from the host 6210 or transmitted to the host 6210 from the memory device 6230. When the RAM 6222 is used as a cache memory, the RAM 6222 may assist the low-speed memory device 6230 to operate at high speed.

The ECC circuit 6223 may correspond to the ECC component 138 of the controller 130 illustrated in FIG. 1. As described with reference to FIG. 1, the ECC circuit 6223 may generate an ECC (Error Correction Code) for correcting a fail bit or error bit of data provided from the memory device 6230. The ECC circuit 6223 may perform error correction encoding on data provided to the memory device 6230, thereby forming data with a parity bit. The parity bit may be stored in the memory device 6230. The ECC circuit 6223 may perform error correction decoding on data outputted from the memory device 6230. The ECC circuit 6223 may correct an error using the parity bit. For example, as described with reference to FIG. 1, the ECC circuit 6223 may correct an error using the LDPC code, BCH code, turbo code, Reed-Solomon code, convolution code, RSC or coded modulation such as TCM or BCM.

The memory controller 6220 may transmit/receive data to/from the host 6210 through the host interface 6224, and transmit/receive data to/from the memory device 6230 through the NVM interface 6225. The host interface 6224 may be connected to the host 6210 through a PATA bus, SATA bus, SCSI, USB, PCIe or NAND interface. The memory controller 6220 may have a wireless communication function with a mobile communication protocol such as WiFi or Long Term Evolution (LTE). The memory controller 6220 may be connected to an external device, for example, the host 6210 or another external device, and then transmit/receive data from the external device. In particular, as the memory controller 6220 is configured to communicate with the external device through one or more of various communication protocols, the memory system and the data processing system t may be applied to wired/wireless electronic devices, particularly a mobile electronic device.

FIG. 11 is a diagram schematically illustrating another example of the data processing system including the memory system in accordance with a present embodiment. FIG. 11 schematically illustrates an SSD to which the memory system may be applied.

Referring to FIG. 11, the SSD 6300 may include a controller 6320 and a memory device 6340 including a plurality of nonvolatile memories. The controller 6320 may correspond to the controller 130 in the memory system 110 of FIGS. 1 and 5, and the memory device 6340 may correspond to the memory device 150 in the memory system of FIGS. 1 and 5.

More specifically, the controller 6320 may be connected to the memory device 6340 through a plurality of channels CH1 to CHi. The controller 6320 may include one or more processors 6321, a buffer memory 6325, an ECC circuit 6322, a host interface 6324 and a is memory interface, for example, a nonvolatile memory interface 6326.

The buffer memory 6325 may temporarily store data provided from the host 6310 or data provided from a plurality of flash memories NVM included in the memory device 6340, or temporarily store meta data of the plurality of flash memories NVM, for example, map data including a mapping table. The buffer memory 6325 may be embodied by volatile memories such as DRAM, SDRAM, DDR SDRAM, LPDDR SDRAM and GRAM or nonvolatile memories such as FRAM, ReRAM, STT-MRAM and PRAM. FIG. 10 illustrates that the buffer memory 6325 exists in the controller 6320. However, the buffer memory 6325 may exist outside the controller 6320.

The ECC circuit 6322 may calculate an ECC value of data to be programmed to the memory device 6340 during a program operation, perform an error correction operation on data read from the memory device 6340 based on the ECC value during a read operation, and perform an error correction operation on data recovered from the memory device 6340 during a failed data recovery operation.

The host interface 6324 may provide an interface function with an external device, for example, the host 6310, and the nonvolatile memory interface 6326 may provide an interface function with the memory device 6340 connected through the plurality of channels.

Furthermore, a plurality of SSDs 6300 to which the memory system 110 of FIGS. 1 and 5 is applied may be provided to embody a data processing system, for example, RAID (Redundant Array of Independent Disks) system. The RAID system may include the plurality of SSDs 6300 and a RAID controller for controlling the plurality of SSDs 6300. When the RAID controller performs a program operation in response to a write command provided from the host 6310, the RAID controller may select one or more memory systems or SSDs 6300 according to a plurality of RAID levels, that is,

RAID level information of the write command provided from the host 6310 in the SSDs 6300, and output data corresponding to the write command to the selected SSDs 6300. Furthermore, when the RAID controller performs a read command in response to a read command provided from the host 6310, the RAID controller may select one or more memory systems or SSDs 6300 according to a plurality of RAID levels, that is, RAID level information of the read command provided from the host 6310 in the SSDs 6300, and provide data read from the selected SSDs 6300 to the host 6310.

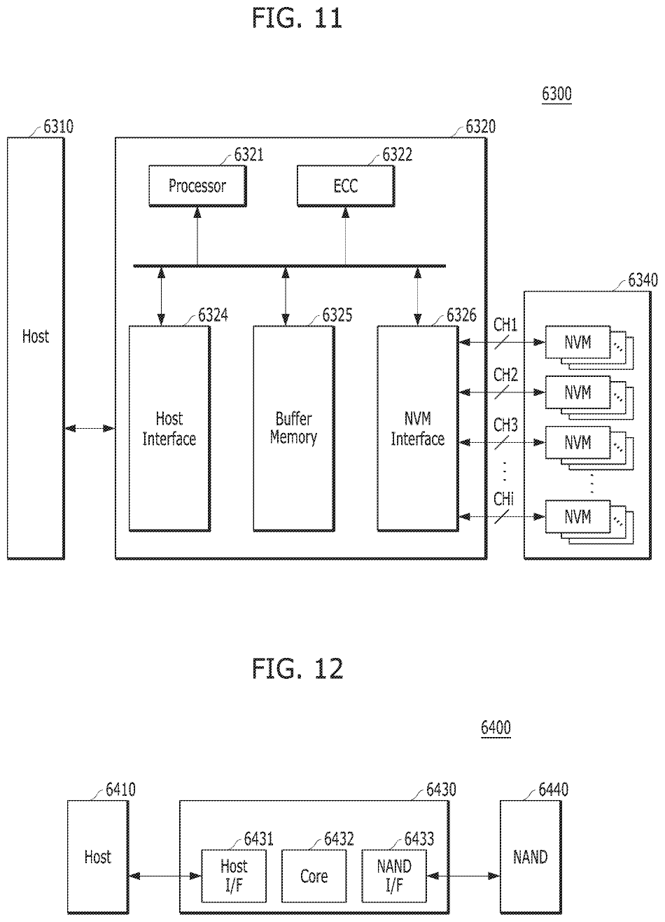

FIG. 12 is a diagram schematically illustrating another example of the data processing system including the memory system in accordance with an embodiment. FIG. 12 schematically illustrates an embedded Multi-Media Card (eMMC) to which the memory system may be applied.

Referring to FIG. 12, the eMMC 6400 may include a controller 6430 and a memory device 6440 embodied by one or more NAND flash memories. The controller 6430 may correspond to the controller 130 in the memory system 110 of FIGS. 1 and 5, and the is memory device 6440 may correspond to the memory device 150 in the memory system 110 of FIGS. 1 and 5.

More specifically, the controller 6430 may be connected to the memory device 6440 through a plurality of channels. The controller 6430 may include one or more cores 6432, a host interface 6431 and a memory interface, for example, a NAND interface 6433.

The core 6432 may control overall operations of the eMMC 6400, the host interface 6431 may provide an interface function between the controller 6430 and the host 6410, and the NAND interface 6433 may provide an interface function between the memory device 6440 and the controller 6430. For example, the host interface 6431 may serve as a parallel interface, for example, MMC interface as described with reference to FIG. 1. Furthermore, the host interface 6431 may serve as a serial interface, for example, UHS ((Ultra High Speed)-I/UHS-II) interface.

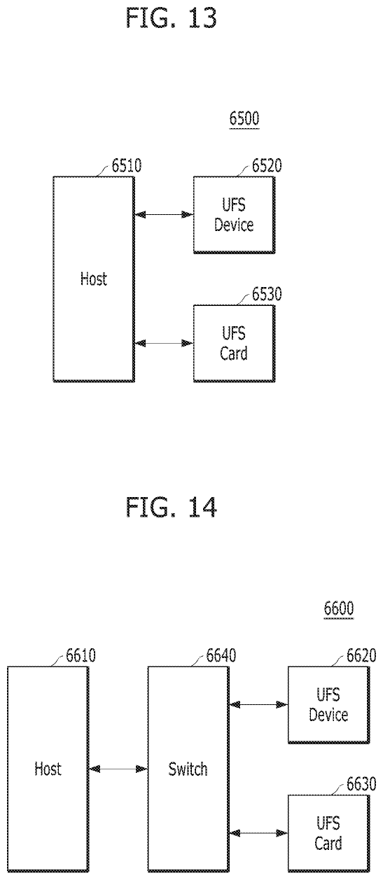

FIGS. 13 to 16 are diagrams schematically illustrating other examples of the data processing system including the memory system in accordance with embodiments. FIGS. 13 to 16 schematically illustrate UFS (Universal Flash Storage) systems to which the memory system may be applied.

Referring to FIGS. 13 to 16, the UFS systems 6500, 6600, 6700 and 6800 may include hosts 6510, 6610, 6710 and 6810, UFS devices 6520, 6620, 6720 and 6820 and UFS cards 6530, 6630, 6730 and 6830, respectively. The hosts 6510, 6610, 6710 and 6810 may is serve as application processors of wired/wireless electronic devices or particularly mobile electronic devices, the UFS devices 6520, 6620, 6720 and 6820 may serve as embedded UFS devices, and the UFS cards 6530, 6630, 6730 and 6830 may serve as external embedded UFS devices or removable UFS cards.

The hosts 6510, 6610, 6710 and 6810, the UFS devices 6520, 6620, 6720 and 6820 and the UFS cards 6530, 6630, 6730 and 6830 in the respective UFS systems 6500, 6600, 6700 and 6800 may communicate with external devices, for example, wired/wireless electronic devices or particularly mobile electronic devices through

UFS protocols, and the UFS devices 6520, 6620, 6720 and 6820 and the UFS cards 6530, 6630, 6730 and 6830 may be embodied by the memory system 110 illustrated in FIGS. 1 and 5. For example, in the UFS systems 6500, 6600, 6700 and 6800, the UFS devices 6520, 6620, 6720 and 6820 may be embodied in the form of the data processing system 6200, the SSD 6300 or the eMMC 6400 described with reference to FIGS. 10 to 12, and the UFS cards 6530, 6630, 6730 and 6830 may be embodied in the form of the memory card system 6100 described with reference to FIG. 9.

Furthermore, in the UFS systems 6500, 6600, 6700 and 6800, the hosts 6510, 6610, 6710 and 6810, the UFS devices 6520, 6620, 6720 and 6820 and the UFS cards 6530, 6630, 6730 and 6830 may communicate with each other through an UFS interface, for example, MIPI M-PHY and MIPI UniPro (Unified Protocol) in MIPI (Mobile is Industry Processor Interface). Furthermore, the UFS devices 6520, 6620, 6720 and 6820 and the UFS cards 6530, 6630, 6730 and 6830 may communicate with each other through various protocols other than the UFS protocol, for example, UFDs, MMC, SD, mini-SD, and micro-SD.

In the UFS system 6500 illustrated in FIG. 13, each of the host 6510, the UFS device 6520 and the UFS card 6530 may include UniPro. The host 6510 may perform a switching operation in order to communicate with the UFS device 6520 and the UFS card 6530. In particular, the host 6510 may communicate with the UFS device 6520 or the UFS card 6530 through link layer switching, for example, L3 switching at the UniPro. The UFS device 6520 and the UFS card 6530 may communicate with each other through link layer switching at the UniPro of the host 6510. In the present embodiment, the configuration in which one UFS device 6520 and one UFS card 6530 are connected to the host 6510 is illustrated as an example. However, a plurality of UFS devices and UFS cards may be connected in parallel or in the form of a star to the host 6410, and a plurality of UFS cards may be connected in parallel or in the form of a star to the UFS device 6520 or connected in series or in the form of a chain to the UFS device 6520.

In the UFS system 6600 illustrated in FIG. 14, each of the host 6610, the UFS device 6620 and the UFS card 6630 may include UniPro, and the host 6610 may communicate with the UFS device 6620 or the UFS card 6630 through a switching module 6640 performing a switching operation, for example, through the switching module 6640 which performs link layer switching at the UniPro, for example, L3 switching. The UFS device 6620 and the UFS card 6630 may communicate with each other through link layer switching of the switching module 6640 at UniPro. In the present embodiment, the configuration in which one UFS device 6620 and one UFS card 6630 are connected to the switching module 6640 is illustrated as an example. However, a plurality of UFS devices and UFS cards may be connected in parallel or in the form of a star to the switching module 6640, and a plurality of UFS cards may be connected in series or in the form of a chain to the UFS device 6620.

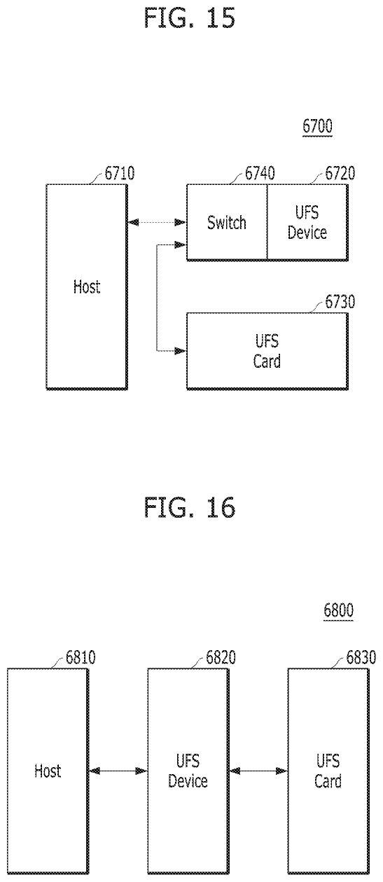

In the UFS system 6700 illustrated in FIG. 15, each of the host 6710, the UFS device 6720 and the UFS card 6730 may include UniPro, and the host 6710 may communicate with the UFS device 6720 or the UFS card 6730 through a switching module 6740 performing a switching operation, for example, through the switching module 6740 which performs link layer switching at the UniPro, for example, L3 switching. The UFS device 6720 and the UFS card 6730 may communicate with each other through link layer switching of the switching module 6740 at the UniPro, and the switching module 6740 may be integrated as one module with the UFS device 6720 inside or outside the UFS device 6720. In the present embodiment, the configuration in which one UFS device 6720 and one UFS card 6730 are connected to the switching module 6740 is illustrated as an example. However, a plurality of modules each including the switching module 6740 and the UFS device 6720 may be connected in parallel or in the form of a star to the host 6710 or connected in series or in the form of a chain to each other. Furthermore, a plurality of UFS cards may be connected in parallel or in the form of a star to the UFS device 6720.

In the UFS system 6800 illustrated in FIG. 16, each of the host 6810, the UFS device 6820 and the UFS card 6830 may include M-PHY and UniPro. The UFS device 6820 may perform a switching operation in order to communicate with the host 6810 and the UFS card 6830. In particular, the UFS device 6820 may communicate with the host 6810 or the UFS card 6830 through a switching operation between the M-PHY and UniPro module for communication with the host 6810 and the M-PHY and UniPro module for communication with the UFS card 6830, for example, through a target ID (Identifier) switching operation. The host 6810 and the UFS card 6830 may communicate with each other through target ID switching between the M-PHY and UniPro modules of the UFS device 6820. In the present embodiment, the configuration in which one UFS device 6820 is connected to the host 6810 and one UFS card 6830 is connected to the UFS device 6820 is illustrated as an example. However, a plurality of UFS devices may be connected in parallel or in the form of a star to the host 6810, or connected in series or in the form of a chain to the host 6810, and a plurality of UFS cards may be connected in parallel or in the form of a star to the UFS device 6820, or connected in series or in the form of a chain to the UFS device 6820.

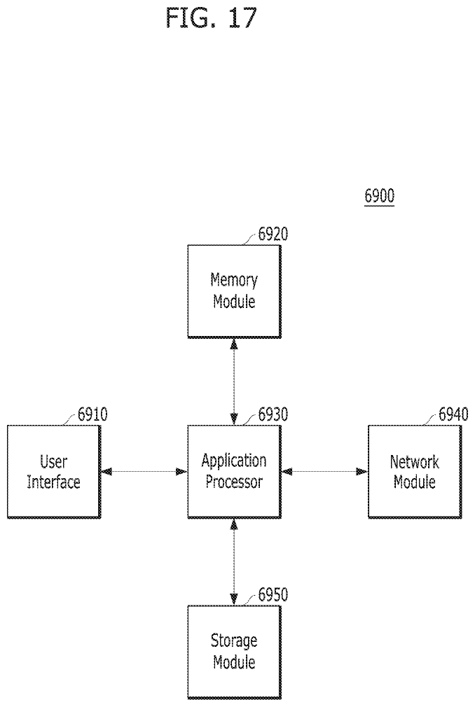

FIG. 17 is a diagram schematically illustrating another example of the data processing system including the memory system in accordance with an embodiment. FIG. 17 is a diagram schematically illustrating a user system to which the memory system may be applied.

Referring to FIG. 17, the user system 6900 may include an application processor 6930, a memory module 6920, a network module 6940, a storage module 6950 and a user interface 691.0.

More specifically, the application processor 6930 may drive components included in the user system 6900, for example, an OS, and include controllers, interfaces and a graphic engine which control the components included in the user system 6900. The application processor 6930 may be provided as System-on-Chip (SoC).

The memory module 6920 may be used as a main memory, work memory, buffer memory or cache memory of the user system 6900. The memory module 6920 may include a volatile RAM such as DRAM, SDRAM, DDR SDRAM, DDR2 SDRAM, DDR3 SDRAM, LPDDR SDARM, LPDDR3 SDRAM or LPDDR3 SDRAM or a nonvolatile RAM such as PRAM, ReRAM, MRAM or FRAM. For example, the application processor 6930 and the memory module 6920 may be packaged and mounted, based on POP (Package on Package).

The network module 6940 may communicate with external devices. For example, the network module 6940 may not only support wired communication, but also support various wireless communication protocols such as code division multiple access (CDMA), global system for mobile communication (GSM), wideband CDMA (WCDMA), CDMA-2000, time division multiple access (TDMA), long term evolution (LTE), worldwide interoperability for microwave access (W max), wireless local area network (WLAN), ultra-wideband (UWB), Bluetooth, wireless display (WI-DI), thereby communicating with wired/wireless electronic devices, particularly mobile electronic devices. Therefore, the memory system and the data processing system can be applied to wired/wireless electronic devices. The network module 6940 may be included in the application processor 6930.

The storage module 6950 may store data, for example, data received from the application processor 6930, and then may transmit the stored data to the application processor 6930. The storage module 6950 may be embodied by a nonvolatile semiconductor memory device such as a phase-change RAM (PRAM), a magnetic RAM (MRAM), a resistive RAM (ReRAM), a NAND flash, NOR flash and 3D NAND flash, and provided as a removable storage medium such as a memory card or external drive of the user system 6900. The storage module 6950 may correspond to the memory system 110 described with reference to FIGS. 1 and 5. Furthermore, the storage module 6950 may be embodied as an SSD, eMMC and UFS as described above with reference to FIGS. 11 to 16.

The user interface 6910 may include interfaces for inputting data or commands to the application processor 6930 or outputting data to an external device. For example, the user interface 6910 may include user input interfaces such as a keyboard, a keypad, a button, a touch panel, a touch screen, a touch pad, a touch ball, a camera, a microphone, a gyroscope sensor, a vibration sensor and a piezoelectric element, and user output interfaces such as a liquid crystal display (LCD), an organic light emitting diode (OLED) display device, an active matrix OLED (AMOLED) display device, an LED, a speaker and a motor.

Furthermore, when the memory system 110 of FIGS. 1 and 5 is applied to a mobile electronic device of the user system 6900, the application processor 6930 may control overall operations of the mobile electronic device, and the network module 6940 may serve as a communication module for controlling wired/wireless communication with an external device. The user interface 6910 may display data processed by the processor 6930 on a display/touch module of the mobile electronic device, or support a function of receiving data from the touch panel.

In accordance with embodiments of the present disclosure, by distinguishing a read operation for a merge operation from a normal read operation, i.e., a read operation for a non-operation, the page buffers in a nonvolatile memory device may be selectively used as caches in the read operation for a merge operation.

Through this, it is possible to efficiently perform a read operation for a merge operation.

Although various embodiments have been illustrated and described, it will be apparent to those skilled in the art in light of the present disclosure that various changes and modifications may be made without departing from the spirit and scope of the invention as defined in the following claims.

What is claimed is:

1. A memory system comprising:
a nonvolatile memory device including dies, each including planes, each including blocks, each including pages, each including a set number of sections, and page buffers for caching data to be outputted from the blocks by page unit;
a host controller suitable for processing an operation with a host; and
a memory controller coupled with the host controller, and suitable for processing an operation with the nonvolatile memory device,
wherein the memory controller:
checks whether a read operation for a read-target block, among the blocks, is for a merge operation,
selects whether to perform a page-buffer-caching-update operation of reading requested data from a page of the read-target block and caching the read data in a corresponding one of the page buffers based on a result of the check, and
receives the cached data from the corresponding page buffer.

2. The memory system according to claim 1,
wherein, in the case where the read operation is for a merge operation, the memory controller checks whether a target address of the read operation is the same as that of the most recently completed read operation, selects whether to perform the page-buffer-caching-update operation, depending on a result of the target address check, and receives the cached data from the corresponding page buffer, and
wherein, in the case where the read operation is not for a merge operation, the memory controller performs the page-buffer-caching-update operation, and receives the cached data from the corresponding page buffer.

3. The memory system according to claim 2,
wherein, in the case where the target address of the read operation is the same as that of a most recently completed read operation, the memory controller does not perform the page-buffer-caching-update operation, and receives the cached data from the corresponding page buffer, and
wherein, in the case where the target address of the read operation is not the same as that of the most recently completed read operation, the memory controller performs the page-buffer-caching-update operation, and receives the cached data from the corresponding page buffer.

4. The memory system according to claim 2, further comprising:
a merge flag,
wherein the host controller sets the merge flag when requesting the read operation to the memory controller to perform the merge operation, and resets the merge flag when requesting the read operation to the memory controller to perform an operation other than the merge operation, and
wherein the memory controller determines whether the read operation is for the merge operation based on a state of the merge flag.

5. The memory system according to claim 2,
wherein, in the case of performing the merge operation, the host controller provides information on victim blocks to the memory controller, and
wherein the memory controller checks whether the read-target block is included in the information on victim blocks, and determines whether the read operation is for the merge operation based on a result of the check of the information on victim blocks.

6. The memory system according to claim 3,
wherein the memory controller manages a read-completed target address table which includes a set number of target addresses of most recently completed read operations and
wherein the memory controller checks whether the target address of the read operation is included in the read-completed target address table, and determines whether the target address of the read operation is the same as that of the most recently completed read operation based on a result of the check of the read-completed target address table.

7. The memory system according to claim 6,
wherein, in the case where the target address of the read operation is included in the read-completed target address table, the memory controller does not perform the page-buffer-caching-update operation, and receives the cached data from the corresponding page buffer, and
wherein, in the case where the target address of the read operation is not included in the read-completed target address table, the memory controller performs the page-buffer-caching-update operation, and receives the cached data from the corresponding page buffer.

8. The memory system according to claim 1, wherein the memory controller transfers the cached data of a page unit received from the corresponding page buffer to the host controller by the page unit, or divides the data by a section unit and transfers the divided data to the host controller by the section unit. The memory system according to claim 1,
wherein the memory controller manages the blocks as a plurality of super blocks by grouping the blocks in a type corresponding to a set condition, and
wherein the memory controller transfers the cached data of a super block unit received from the corresponding page buffer to the host controller by the super block unit, or divides the requested data by a page unit and transfers divided data to the host controller by the page unit.

10. The memory system according to claim 9,
wherein a first die of the dies is coupled to a first channel, a second die of the dies is coupled to a second channel, planes in the first die are coupled to first ways which share the first channel, and planes in the second die are coupled to a second ways which share the second channel, and according to the set condition
the memory controller groups a first block in a first plane of the first die and a second block in a second plane of the first die and groups a third block in a third plane of the second die and a fourth block in a fourth plane of the second die,
the memory controller groups a first block in a first plane of the first die and a third block in a third plane of the second die and groups a second block in a second plane of the first die and a fourth block in a fourth plane of the second die, or
the memory controller groups a first block in a first plane of the first die, a second block in a second plane of the first die, a third block in a third plane of the second die and a fourth block in a fourth plane of the second die.

11. A method for operating a memory system including a nonvolatile memory device including dies, each including planes, each including blocks, each including pages, each including a set number of sections, and page buffers for caching data to be outputted from the blocks, by page unit; a host controller suitable for processing an operation with a host; and a memory controller coupled with the host controller, and suitable for processing an operation with the nonvolatile memory device, the method comprising:
a first step of checking, by the memory controller, whether a read operation for a read-target block, among the blocks is for a merge operation;
a first step of selecting whether to perform a page-buffer-caching-update operation of reading requested data from a page of the read-target block and caching read requested data in a corresponding one of the page buffers based on a result of the first checking step, through control of the memory controller; and
transferring, after the first selecting step, the cached data from the corresponding page buffer of the nonvolatile memory device to the memory controller.

12. The method according to claim 11, wherein the first selecting step comprises:
a second step of checking, in the case where it is determined that the read operation is for a merge operation, whether a target address of the read operation is the same as that of the most recently completed read operation;
a second step of selecting whether to perform the page-buffer-caching-update operation based on a result of the second checking step; and
a first update step of performing the page-buffer-caching-update operation in the case where it is determined that the read operation is not for a merge operation,
wherein the transferring step is performed after the second selecting step or the first update performing step.

13. The method according to claim 12, wherein the second selecting step comprises:
not performing the update operation in the case where it is determined that the target address of the read operation is the same as that of the most recently completed read operation; and
a second update step of performing the page-buffer-caching-update operation in the case where it is determined that the target address of the read operation is not the same as that of the most recently completed read operation,
wherein the transferring step is performed after not performing the update operation or after the second update performing step.

14. The method according to claim 12,
wherein the memory system further includes a merge flag, and
wherein the first checking step comprises:
setting the merge flag by the host controller when the host controller requests the read operation to the memory controller to perform the merge operation;
resetting the merge flag by the host controller when the host controllers requests the read operation to the memory controller to perform an operation other than the merge operation; and
determining, by the memory controller, whether the read operation is for the merge operation based on a state of the merge flag, when the read operation is requested to the memory controller.

15. The method according to claim 12, wherein the first checking step comprises:
providing, in the case of performing the merge operation, information on victim blocks to the memory controller by the host controller; and
checking, when the read operation is requested to the memory controller, whether the read-target block is included in the information on victim blocks, and determining whether the read operation is for the merge operation based on a result of the checking the information on victim blocks, by the memory controller.

16. The method according to claim 13, wherein the second checking step comprises:
managing, by the memory controller, a read-completed target address table which includes a set number of target addresses of most recently completed read operations; and
a third checking step of checking whether the target address of the read operation is included in the read-completed target address table, and determining whether the target address of the read operation is the same as that of the most recently completed read operation based on a result of the third checking step.

17. The method according to claim 16, wherein the second selecting step comprises:
not performing the page-buffer-caching-update operation in the case where the target address of the read operation is included in the read-completed target address table; and
a third update step of performing the page-buffer-caching-update operation in the case where the target address of the read operation is not included in the read-completed target address table,
wherein the transferring step is performed after not performing the page-buffer-caching-update operation or after the third update performing step.

18. The method according to claim 11, wherein the transferring step further comprises:
transferring the requested data to the memory controller by page unit, and transferring the cached data to the host controller from the memory controller by page unit; or
transferring the requested data to the memory controller by page unit, and dividing the received data by section unit, and transferring the divided data to the host controller from the memory controller by section unit.

19. The method according to claim 11, further comprising:
managing, by the memory controller, the blocks as a plurality of is super blocks by grouping the blocks in a type corresponding to a preset condition;
transferring the cached data to the memory controller by super block unit in the transferring step, and transferring the received cached data to the host controller from the memory controller by super block unit; and
transferring the cached data to the memory controller by super block unit in the transferring step, and dividing the received cached data by page unit, and transferring the divided data to the host controller from the memory controller by page unit.

20. The method according to claim 19,
wherein a first die of the dies is coupled to a first channel, a second die of the dies is coupled to a second channel, planes in the first die are coupled to first ways which share the first channel, and planes in the second die are coupled to second ways which share the second channel, wherein according to the set condition, the method further comprises:
grouping a first block in a first plane of the first die and a second block in a second plane of the first die and grouping a third block in a third plane of the second die and a fourth block in a fourth plane of the second die,
grouping a first block in a first plane of the first die and a third block in a third plane of the second die and grouping a second block in a second plane of the first die and a fourth block in a fourth plane of the second die, or
grouping a first block in a first plane of the first die, a second block in a second plane of the first die, a third block in a third plane of the second die and a fourth block in a fourth plane of the second die.
